(19) United States
(12) Patent Application Publication
(10) Pub. No.: US 2002/0051360 A1
(43) Pub. Date: May 2, 2002

(54) Method and apparatus for unifying light beams

(76) Inventors: Vladimir Vadimovich Solodovnikov, Moskovskaya obl. (RU); Anatoly Fedorovich Lavrov, Moscow (RU)

Correspondence Address: BAKER & BOTTS, 30 ROCKEFELLER PLAZA, NEW YORK, NY, 10112

(21) Appl. No.: 09/846,567

(22) Filed: Apr. 30, 2001

Related U.S. Application Data
(63) Continuation-in-part of application No. 09/783,475, filed on Feb. 14, 2001.
(63) Continuation-in-part of application No. PCT/RU98/00363, filed on Nov. 4, 1998.

(30) Foreign Application Priority Data
Dec. 18, 2000 (IL) 140,386

(51) Int. Cl. F21V 5/00; F21K 2/00

(52) U.S. Cl. 362/244; 362/259; 362/237; 362/551

(57) ABSTRACT

A light unifier, which comprises a plurality of light sources, particularly laser diodes, emitting parallel light beams of a rectangular cross-section, for focusing the light energy of all the beams onto a target area through beam-shaping means, which comprises transverse collimators, means for juxtaposing the emitted beams to form a unified beam, a longitudinal collimator for longitudinally collimating the unified beam, and means for focusing it onto the target area. The light beams have a transverse and a longitudinal divergence and the ratio of the transverse divergence to the longitudinal divergence is higher than 1. The transverse collimators are placed at such a distance from the sources that, at the point at which the beams reach them, the sum of the short sides of the beams is equal to the long side of each of them at the point at which they reach the longitudinal collimator. The number of light sources is such as to permit to obtain a unified beam that has a square cross-section and the same divergence on all its sides. Two groups of laser diodes may be arranged in parallel or mutually perpendicular planes and the unified beams produced by them are focused together onto the target area.

### SPECIFICATION

This application is a continuation-in-part of application Ser. No. 09/783,475 filed Feb. 14, 2001. This application is also a continuation-in-part of PCT/RU/00363 filed Nov. 4, 1998 designating the U.S. and published in Russian on May 11, 2000 as WO 00/27002. This application additionally claims priority from Israeli Patent Application No. 140,386 filed Dec. 18, 2000

### FIELD OF THE INVENTION

The present invention relates to a method and a device for unifying the beams produced by light sources, particularly laser diodes, so as to obtain a unified beam having high power, high brightness and high output density, adapted to be focused especially on optical fiber cross-sections.

### DESCRIPTION OF THE PRIOR ART

One of the problems of great importance in laser engineering consists in providing coherent light sources having high brightness and high power output density wherein such light could be coupled e.g. into an optical fiber of 50 μm diameter.

Known are various structures of high brightness light-emitting adders or light unifiers, as will be called hereinafter devices combining the emissions of a plurality of light sources, including those comprising laser diodes. In these systems, individual sources have a stripe-geometry emission region in the cross-sectional plane perpendicular to the optical axis of the respective source. In order to fit, the light energy e.g. into an optical fiber, it is necessary to obtain a substantially circular spot on the target area thus reducing the energy loss. The conventional structures, as well as that described in the paper by T. Y. Fan and Antonio Sanchez, IEEE Journal of Quantum Electronics (1990), Vol. 26, No. 2, pp. 311-316, use anamorphic, collimating and shaping means ensuring a quasi total illumination of the target area while having isolated regions of each source's beams propagation within the acceptance angle from the focusing means to the focusing zone where said target area is located.

Another light-emitting adder or light unifier disclosed in U.S. Pat. No. 5,463,534 comprises at least two light sources with identical stripe geometry of the emission regions. The light-emitting stripes of the output ends have their mutually perpendicular sides with a long dimension and a short dimension in the cross-sections perpendicular to the optical axes of the light sources. Said right sources are spaced apart from the focusing zone at distances equal to the optical lengths L as calculated from each individual source to the focusing zone taking into account the refractive indices of the medium along the beam path (see Handbook of General Physics, Vol, 3, G. S. Landsberg, “Optics”, State Publishing House for Engineering and Theoretical Literature, Moscow, 1952. p. 84). In the above-mentioned known system. the optical lengths L, μm, differ from source to source.

Provided between the light sources and the focusing zone are imaging means comprising beam shaping means allowing to collimate the beam in mutually perpendicular directions parallel to the sides of the light-emitting stripe, and focusing means to focus the collimated beams onto the focusing zone accommodating the target area.

In such a light-emitting adder, the required illumination of the target area is obtained with the aid of cylindrical telescopes, as well as collimating and focusing means included in said imaging means, said focusing means having substantially equal focal lengths in X-axis and Y-axis. The inventors emphasized the fact that within the acceptance angle between the focusing means and the target area, the beams emitted by each light source occupy well defined different spaces without propagating through the adjacent regions. Consequently, the resultant beam will include, as regards its spectral parameters and wavelengths, the entire spread characteristic of the individual light, sources. Problems then arise, especially in the case of laser diodes, in achieving a maximum output brightness with a minimum number of original light sources used, such problems being particularly critical when need is felt to deliver the light energy into an optical fiber.

WO 92/02844 describes a High Power Light Source, comprising a number of laser diodes, wherein the laser beams are collimated by a lens, are anamorphically expanded/reduced so that the width of each beam in the X-axis is increased in relation to the width in the Y-axis, and then are focused onto an optical fiber by a further lens.

WO 91/12641 describes a Solid State Laser Diode Light Source, which comprises at least two laser diodes, wherein the beams of the diodes are combined by a polarizing beam combiner and are focused by a lens onto an optical fiber. The beams are acted on in the long direction of the laser stripes by anamorphic beam shaping means to reduce the length of the image formed at the end of the fiber.

It is a purpose of this invention to provide an optical device, herein called light-emitting adder or light unifier, which fully achieves the results desired in this branch of the art, viz. unifies the beams emitted by different light sources, particularly laser sources, into a single beam with maximum optical yield, by “optical yield” being meant herein the ratio of the optical energy that is delivered to the target to the sum of the optical energies emitted by the several light sources.

It is another object of the invention to provide such a device which produces a beam that is adapted to be fed into an optical fiber.

It is a further purpose of the invention to provide such a device wherein the light sources are laser sources.

It is a still further object of this invention to provide such a device which has extremely limited dimensions.

It is a still further purpose of this invention to provide such a device which has a limited cost.

It is a still further purpose of this invention to provide a method for unifying the beams produced by several light sources, particularly laser sources, into a single beam with the highest optical yield.

It is a still further purpose of this invention to provide such a method for unifying beams of several light sources so as to produce a unified beam of high and uniform brightness.

Other purposes and advantages of this invention will appear as the description proceeds.

### DESCRIPTION OF THE INVENTION

The invention aims to provide a light-emitting adder or light unifier, which comprises a plurality of light sources, particularly laser sources, each of which emits a beam having a rectangular cross-section in a plane perpendicular to the source optical axis, viz. perpendicular to the direction of propagation of the emitted beam. Said cross-section has a long side and a short side. The long side will be called herein the longitudinal side and the short side will be called the transverse side. In a system of Cartesian coordinates, the X axis will be considered to be parallel to the longitudinal direction, the Y axis to the transverse direction, and the Z axis to the direction of propagation of the beam. In rectangular laser beams, the ratio of the long side of the rectangular cross-section to the short side is high, e.g., 20/1 or 120/1. Beams of such cross-section are produced by laser sources well known in the art, for instance SDL-6370-A, SDL-6380-A, SDL-6380-L-2, S-915-500C-50-x, S-915-1000C-100-x and S-915-1500C-150-x. Hereinafter, reference will be made to laser sources both for purposes of description and because they are the preferred light sources, but this should not be construed as a limitation, since the invention can be applied to light sources other than laser.

It is well known that the divergence of the laser beams in the transverse direction is much larger than the divergence in the longitudinal direction. In other words, the transverse, numerical aperture NAy of the laser beams is much greater than the longitudinal, numerical aperture NAx: e.g. NAy=0.5 and NAy=0.1. Because of the divergence, the beams assume a frusto-pyramidal configuration, viz. they are bound by four slanted planes, two longitudinal and two transverse ones, each which makes an angle with one of the two planes of symmetry of the beams (one longitudinal and one transverse), the intersection of which is the axis of propagation of the beam. The term “divergence” is often used to indicate the angle between the aforesaid two longitudinal and the two transverse slanted planes respectively. In this application, however, the angle (pa of each longitudinal slanted plane with the longitudinal axis of symmetry of the beam is defined as the longitudinal divergence half-angle, and the angle φb of each transverse slanted plane with the transverse axis of symmetry of the beam is defined as the transverse divergence half-angle, the ratio φb/φa being larger than 1, e.g. 5.

The light unifier is structured so as to provide a final concentrated beam impinging on a target area. The length of the path traveled by each beam from its source to the target will be called “the optical length” of the source and indicated by L; and the differences between the optical lengths of any two sources will be indicated by ΔL.

The adder comprises:

1—a plurality of laser sources;

2—means for collimating the emitted laser beams in the Y-direction, said means being located close to the sources, viz. close to the origin of the beams, to reduce their lateral divergence;

3—beam unifying means, for juxtaposing the laser beams collimated in the Y-direction to form what will be called a unified beam;

4—means for collimating the unified beam in the X-direction for obtaining a substantially square, final, concentrated beam; and

5—means for focusing said concentrated beam at or near the target.

Preferably, the ratio of the differences L of the optical paths of any two laser sources is not greater than one tenth of said optical paths, viz. ΔL/L≦0.1.

According to an aspect of the invention, the light unifier comprises, between the sources and the target area, a device that will be called “beam-shaping means”, which comprises the following components:

1—means for collimating each of the several emitted beams in the transverse direction, hereinafter “transverse collimators”;

2—means for juxtaposing said beams to form what will be called a unified beam;

3—means for imparting to the unified beam a square cross-section;

4—means for collimating the unified beam in the longitudinal direction, hereinafter “longitudinal collimator”, when the unified beam has been imparted a square cross-section; and

5—means for focusing the collimated, unified beam onto the target area.

In addition to having a square cross-section, the unified beam should have the same divergence along all its sides, and the light unifier of the invention comprises means for imparting to the unified beam the same divergence along all its sides, as will be explained hereinafter.

According to the invention, the transverse collimators eliminate the transverse divergence of the individual beams. In order finally to obtain a square unified beam, they should be placed at such a distance from the sources that the sum of the transverse dimensions of the beams equals the longitudinal dimension of the unified beam at the point at which it impinges on the longitudinal collimator. If the long and the short sides of the beams at the source are A and B respectively, and the beams travel paths of length d from the sources to the transverse collimators and paths of length D from said transverse collimators to said longitudinal collimator, their long sides, when they impinge on said longitudinal collimator, will be A+2(d+D)tangφa. The short side of each beam will be B+2dtangφb. If there are “n” sources, the condition for imparting to the unified beam a square cross-section will be expressed by A+2(d+D)tangφa=n(B+2dtangφb).

D+d is the optical length of the various beams minus the distance from the longitudinal collimator to the target area. For purposes of description, it will be called hereinafter “the primary optical length”. It is a structural parameter of the apparatus of the invention. If all optical lengths are equal for all the sources, the primary optical lengths are also equal. If the beam sides at the sources A and B, their divergence half-angles and the number n of source are given in a particular embodiment of the invention, the said formula will permit to calculate the position of the several transverse collimators. If there are differences between the optical lengths of different sources, the above formula permits to calculate the position of each transverse collimators. The condition for obtaining a square beam can be expressed verbally, as follows: the transverse collimators are placed at such a distance from the sources that the sum of the short sides of their beams at the point at which at which the beams reach the respective transverse collimators is equal to the long side of each of them at the point at which the beams reach the longitudinal collimator. If the transverse collimators do not annul the transverse divergences, the residual transverse divergences of the beams will cause a partial overlapping of the individual beams in the unified beam, which is not only possible, but even desirable, an overlap of from 10 to 40% of the cross-sectional areas of any one of the overlapping beams being preferred. It will cause some transverse expansion of the individual beams before they are unified. Further, it will cause some transverse expansion of the unified beam. These expansions, generally minor ones, will not be considered in the following description, but they can easily be accounted for by any expert persons to continue to satisfy the above condition.

As stated above, the unified beam should have the same divergence along all its sides. For this to occur, a condition that may be called “the equal divergence condition” should be satisfied. Said condition is expressed as

NA//beam=NA⊥beam≦NAfiber, (1)

where NA//beam=sin φa is the longitudinal numerical aperture of the emitted beam;

NA⊥beam=sin φb is the transverse numerical aperture of the emitted beam and

NAfiber is the numerical aperture of a fiber.

The numerical apertures of the beam are related to the numerical apertures of the emitting body, designated hereinafter as NA//diode and NA⊥diode, wherein the use of the word “diode” to designated the emitting body is not to be construed as a limitation. Said emitting body apertures are respectively:

NA//diode (longitudinal numerical aperture of the emitting body)=sin φa

NA⊥diode (transverse numerical aperture of the emitting body)=sin φb

φa and φb are the divergence half-angles along the diode slow and fast axes, respectively. The beam numerical apertures are derived as follows:

According to the Lagrange -Helmhotz theorem,

A×NA//diode=H×NA//beam and (2)

B×NA⊥diode=h×NA⊥beam, (3)

where H is the long side (the length) of the unified beam at the longitudinal collimator: and h is the short side (the width) of the individual collimated beams making up the unified beam. A and B are, as hereinbefore, the long and the short side, respectively, of the beams at the source.

Using formulae (1)-(3), one can write

H/h=A×NA//diode/(B×NA⊥diode) (4).

This formula is valid if NA//beam=NA⊥beam, and this condition is achieved by suitable optical design, wherein the lengths of the collimators are chosen to equalize the aforesaid longitudinal and transverse numerical apertures.

Thus, the equal divergence condition defines the ratio of H to h.

Remembering that the long side of the beams, when they impinge on the longitudinal collimator, is A+2(d+D)tan gφa and the short side is B+2d tan gφb, one can write

H=A+2(d+D)tan φa and (5)

h=B+2d tan φb. (6)

Since A and B are negligible in comparison with 2(d+D)tan θa and 2d tan θb, respectively, and d is small in comparison with D, equations (5) and (6) are approximated by

H=2D tan φa and (7)

h=2d tan φb (8)

H/h=A×NA//diode/(B×NA⊥diode) (4)

H=2D tan φₐ (7)

h=2d tan φ_{b} (8)

$$\frac{H}{h} = \frac{2 D tan {ϕ}_{a}}{2 d tan {ϕ}_{b}} = \frac{A \times NA // diode}{B \times NA ⊥ diode}$$

NA // diode=sin φₐ

NA ⊥ diode=sin φ_{b}

$$\frac{D cos {ϕ}_{b}}{d cos {ϕ}_{a}} = \frac{A}{B}$$

Using (4), (7) and (8), one has:

D/d=A cos φa/(B cos φb)

d/D=B cos φb//(A cos φa). (9)

For example, A=100 μm, B=1.3 μm, d=1.28 mm, D+d=55.5 mm, φa=6°, and φb≅34°.

Equation (9) exhibits the relation between d and D. It is seen that they are interrelated. Thus, formulae (4) and (9) relate the parameters of the optical scheme to each other.

The condition of the squareness of the unified beam is:

H=nh, (10)

where n is the number of individual beams (or, in other words, the number of light sources) making up the square unified beam.

This condition defines the number of laser diodes to achieve a square cross-section of the unified beam.

Formulae (10) and (4) give:

n=H/h=A×NA//diode/(B×NA⊥diode)=A sin φa/(B sin φb). (11)

Thus, the equal divergence condition in combination with the squareness condition defines the number of individual beams making up the unified beam. In other words, these conditions unambiguously define the number of laser diodes used to achieve the unified beam with a square cross-section and the same divergence along the square sides.

The following particular example is given by way of illustration:

Assuming as optical parameters:

A=100 μm, B=1.3 μm, NA//diode=0.1, NA⊥diode=0.55, φa=6°, and φb≅34°,

the number of diodes is

n=100 μm×0.1/(1.3 μm×0.55)=13.9≅14.

This means that only 14 beams can make up a unified square beam with the same divergence along its sides for the given optical parameters.

A deviation from said number may permit to obtain a unified beam that is rectangular rather than square and not with the same divergence along its sides concurrently.

The interrelation between the parameters of an emitting body and the optical scheme of the light unifier, on the one hand, and the parameters of an optical fiber, on the other, is now considered.

Inequality (1) relates the NAs of an emitting body to that of an optical fiber:

NA//beam≦NAfiber, (1).

To equations (2) and (3), a term can be added representing a fiber:

A×NA//diode=H×NA//beam=k×Dfiber×NAfiber and (11)

B×NA⊥diode=h×NA⊥beam=k×Dfiber×NAfiber, (12)

In these equations Dfiber is the diameter of the fiber. NAfiber is the numerical aperture of the fiber, which aperture is sin φ, wherein φ is the maximum half entrance angle, viz. the maximum angle from the fiber axis at which light beams can enter the fiber. k<1 is a coefficient taking into account the difference between the round fiber cross-section and the square cross-section of the unified beam, which coefficient k should be as close to 1 as possible.

Formulae (1), (11) and (12) show the interrelation between the parameters of an emitting body and the optical parameters of the light unifier, on the one hand, and the parameters of the optical fiber onto which the unified beam is to be targeted, on the other.

The transverse collimators may be any suitable optical devices, for example, in their simplest form, cylindrical lenses the optical axis of each of which is parallel to the longitudinal direction of the beam which it collimates.

The means for juxtaposing the several individual light beams to form a unified beam—which may be called “the beam adder”—comprises means for deflecting the beams, preferably reflective means such as prisms or mirrors. It is preferred, but not necessary, that the deflection be by an angle of 90° and leave the beams parallel to one another. By effecting the deflection of different beams at suitable points along their path, the deflected beams are caused to become juxtaposed to one another. The beam deflectors are so located as to make the optical paths of the several beams as close as possible. Some differences in the lengths of the optical paths from beam to adjacent beam are tolerable, though it is desirable that they should not exceed 10%, and preferably should not exceed 8%, of said optical paths.

The longitudinal collimator may be any suitable optical device, but its simplest form is a cylindrical lens having its optical axis parallel to the transverse direction of the beams. It is such as to annul the longitudinal divergence of the unified beam, so that said unified beam, which is square when it impinges on the longitudinal collimator, should remain square thereafter.

Finally, the focusing means may be constituted by any suitable optical device, but in the simplest form, is constituted by a spherical lens which concentrates the square, unified beam to a size depending on the size of the target and as equal as possible to it. If the target is an optical fiber, the focusing means will reduce the square cross-section of said unified beam so that it is inscribed in the round cross-section of the optical fiber, or said round cross-section is inscribed in said square cross-section, or said square and round cross-sections will overlap in most of their areas. In this way the loss of optical energy, due to portions of the unified beam falling outside the cross-section of the optical fiber, is minimized. If the target does not have a round cross-section, the focusing means will concentrate the unified beam in such a way as to minimize the loss of optical energy.

It is to be noted that the focusing means need not focus the unified beam directly onto the target. It focuses the unified beam onto a target area, and if the target is not in the target area, the focused beam may be transferred by any suitable optical device, without change of shape or size, or with such changes that, may be desired in particular instances, from the target area to the target. Therefore, a distinction must be made between the target area, which is a geometrical element, and the target itself, which is a physical element.

The combination of transverse collimators, beam adder, longitudinal collimator and focusing means, is called collectively “beam-shaping means”.

Certain features of the beam-shaping means are essential: firstly, that the individual, emitted beams should be brought to juxtaposition or partial overlap, to form a square unified beam, before they are collimated in the longitudinal direction; and secondly, that the individual, emitted beams should be brought to juxtaposition or partial overlap, to form the unified beam, by deflecting them.

According to an embodiment of the invention, the light-emitting adder or light unifier of the invention comprises at least two light sources with stripe-geometry emission regions in the sections perpendicular to the optical axes of said light sources, the mutually perpendicular sides of the light-emitting stripes at the output ends of said light sources having a long dimension and a short dimension, a target area and imaging means, interposed between said light sources and a focusing zone and including beam-shaping means provided with means for collimating beams in mutually perpendicular directions parallel to the sides of said light-emitting stripes, as well as focusing means for focusing onto said focusing zone, the output end of each light source being spaced apart from said focusing zone at distances equal to the optical lengths L. Said light sources are selected in order to allow the longitudinal emission at one at least wavelength a,, and are located in a plane perpendicular to the long or the short dimension of said light emitting stripes, viz. perpendicular or parallel to the long dimensions. The values of optical lengths are selected within the range L−ΔL÷L+ΔL, where the deviation ΔL of the optical lengths is preferably taken so as not to exceed 10% of said optical lengths L. Said beam-shaping means are provided, at the light sources' end and for each of them, with means for collimating beams in the direction parallel to the short dimension of each stripe. There is further provided at least one beam-transporting means capable, on at least a part of its extent, of partly overlapping the beams, and downstream of said beam-transporting means, within said beam-shaping means, there are positioned means for collimating beams in the direction parallel to the long dimension of the stripe. It should be understood that the “overlapping” of beams, which could also be called “mixing”, is always partial, and this should always be understood as implicit, even if not stated, every time that the term “overlapping” is used hereinafter.

In certain cases, such a light-emitting adder may comprise light sources made in the form of either stripe-shaped laser diodes or stripe-shaped superluminescent diodes.

In a preferred embodiment of the invention, the laser diodes of the light-emitting adder of the invention are located, symmetrically with respect to an axis passing through the center of the target, in a plane perpendicular to the long or the short dimension of the light-emitting stripes. Said axis is called herein the optical axis of the adder. The provision of beam-shaping means, having spaced-apart means ensuring the collimation along different axes parallel to the respective sides of said stripes, with beam-transporting means placed therebetween, as well as in the selection of substantially equal optical lengths L differing from one another by predetermined deviations ±ΔL depending on the kind of the light source, result, when taken in combination, in new performances and output characteristics of the light-emitting adder such as increased brightness and power output density with, at the same time, a lower number of light sources, simplified manufacturing process and beam positioning, and lesser energy loss.

Also, preferably, the optical lengths of different light sources are such that they differ from one another not more than by a value ΔL in the range of 2 to 8% of said optical lengths L, viz. ΔL/L=0.02÷0.08.

The combination of the structural features of the light-emitting adder of the invention results in increased brightness and power output density with, at the same time, a lower number of light sources, a simplified manufacturing process and beam positioning, and lesser energy loss.

In an embodiment of the invention, reflecting means are provided in the target area for reflecting a beam or each of a number of beams, originating from a light source, to another light source.

In another embodiment of the invention, the laser diodes are located symmetrically with respect to the optical axis of the adder, one of the diodes, which will be called the pilot source, being located on said axis and the other diodes being in phase with said pilot; source and satisfying what will be called “the coherence condition”, according to which the deviations ΔL of the optical lengths of the sources and the deviations δλ of the wavelengths of the light emitted by said sources, satisfy for at least one pair of laser diodes located symmetrically on opposite sides of the adder's optical axis, the coherence condition ΔL≦πλ²/8δλ (see Kolomiytsev “Interferometers”, “Mashinostroyeniye” publishers, Leningrad Division, 1979. p. 85), leading to a further increase in the brightness and the power output density of the light provided by the adder. For the laser diodes, if any, that do not satisfy said condition, the deviations ΔL of the optical lengths is taken so as not to exceed 10% of said optical lengths L.

It has been found that the aforesaid features of the light-emitting adder of the invention, particularly if it is provided with beam-transporting means capable of partially overlapping beams from different light sources, allow to obtain a regular illumination of the target area positioned within the focusing zone, wherein the brightness in the center of said area is substantially the same as at its periphery. In the case of an optical fiber, the total required emissive power will be delivered across its whole diameter.

According to another embodiment of the invention, the light-emitting adder comprises at least two light sources with stripe geometry emission regions in the sections perpendicular to the optical axes of said light sources, the mutually perpendicular sides of the light-emitting stripes at the output ends of said light sources having a long dimension and a short dimension, a target area and beam-shaping means interposed between said light sources and a focusing zone. The beam-shaping means include means for collimating beams in mutually perpendicular directions parallel to the sides of said light-emitting stripes, as well as focusing means for focusing onto said focusing zone. The output end of each light source is spaced apart from said focusing zone at distances equal to the optical lengths L. Said light source, in the form of laser diodes, are selected in order to allow the emission at one at least wavelength λ, and are located in a plane perpendicular to the long or to the short dimension of said light-emitting stripes. Said beam-shaping means are provided, at the laser diodes' end and for each of them, with means for collimating the beams in the direction parallel to the short dimension of each stripe. Preferably, the device also comprises at least one beam-transporting means capable, on at least a part of its extent, of overlapping the beams. There is also positioned, downstream of said beam-transporting means within said beam-shaping means, collimating means for collimating beams in the direction parallel to the long dimension of the stripes. Preferably, there is further provided, in said focusing zone, at least partly reflecting means. The values of optical lengths L is selected within the range L−ΔL÷L+ΔL, where ΔL is the deviation of said optical lengths L, and the combination of deviations ΔL of the optical lengths and deviations δλ of the wavelengths, for at least one pair of laser diodes located symmetrically about the adder's optical axis, is taken so as to satisfy the coherence condition, i.e. ΔL≦πλ²/8δλ, whereas for the remaining laser diodes, the deviation ΔL of the optical lengths is taken so as not to exceed 10% of said optical lengths L.

This embodiment of the light-emitting adder, wherein the deviations ΔL of the optical lengths and Δλ of the wavelengths of the laser diodes selected as light sources are taken, for at least two laser diodes, so as to satisfy the coherence condition, has the feature that it comprise at least partly reflecting means which allow to improve the characteristics of the symmetric emitters due to their reciprocal influence, thus enabling, combined with the proposed beam-shaping means, the self-adjustment of the entire light-emitting adder and, hence, of the totality of laser diodes. This results in new performances and output characteristics of the light-emitting adders.

The suggested ranges of differences of wavelengths and optical lengths of the laser diodes chosen in order to satisfy the coherence condition, as well as the adopted arrangement of the structural components used, allow to obtain an integrated, substantially coherent light beam of required diameter and brightness. In the plane perpendicular to the long or short dimension of the light-emitting stripes, the individual collimated coherent beams emitted by each source are brought into a well packed integrated light beam characterized by a predetermined, at least partial mixing of the adjacent beams on at least a part of the path within said beam-transporting means. After having passed through said beam-transporting means, the resulting integrated beam is collimated in the perpendicular plane and has substantially equal optical lengths over the entire cross-section. Such an integrated beam produced in the proposed unique structure can be considered, to a very low degree of approximation, as a single beam. Moreover, the provision of at least partly reflecting means leads as well to an increased coherence of the integrated light beam over its entire cross-section. Therefore thanks to the above unobvious and novel essential features of the light-emitting adders, it becomes possible to considerably enhance the brightness and the concentration of the beam in the center of the focusing zone with a very low divergence on the periphery of the resulting spot.

According to a still further embodiment of the invention, the light-emitting adder comprises two laser diode systems, the optical axes of which are at an angle, preferably a right angle, to one another. Each of said systems comprises one laser sources or a plurality of laser sources emitting rectangular beams having a long longitudinal side (X-side) and a short transverse side (Y-side), and comprises means for collimating in the Y-direction close to the sources, adding means for juxtaposing the laser beams collimated in the Y-direction, and means for collimating in the X-direction to obtain a square beam, all as hereinbefore described. Preferably each system comprises a pilot source located on the optical axis of the system, the other sources being arranged in pairs symmetrically on the two sides of the optical axis. However, in this embodiment, means are provided for adding or merging the juxtaposed and collimated laser beams of the two systems and for polarizing them, to form a single final or added beam, which is polarized; and means are further provided for focusing said polarized beam onto the target area. In each of said systems at least one pair of laser diodes, located symmetrically on opposite sides of the system's optical axis, satisfy the aforesaid coherence condition, while for the laser diodes, if any, that do not satisfy said condition, the deviations ΔL of the optical lengths is taken so as not to exceed 10% of said optical lengths L.

In said embodiment, all the light sources are laser diodes, selected in order to allow the emission at one at least wavelength λ and arranged so as to have at least two sources in each of two mutually perpendicular planes, each of these planes being perpendicular to the long dimension of the respective light-emitting stripes. Imaging means are provided, which comprise, in addition to said first beam-shaping means, second beam-shaping means, both said beam-shaping means being coupled to at least two light sources and provided at said sources' end and for each of them, with means for collimating beams in the direction parallel to the short dimension of the light-emitting stripe. Said first beam-shaping means further includes at least one beam-transporting means capable, on at least a part of its extent, of overlapping the beams. Said second beam-shaping means also incorporate at least one beam-transporting means capable, on at least a part of its extent, of overlapping the beams. There is positioned, downstream of said beam-transporting means, within each of said beam-shaping means, one collimating means for collimating beams in the direction parallel to the long dimension of the light-emitting stripes, the respective optical axes of said beam-shaping means being mutually perpendicular. There is additionally provided, at their intersection downstream of said beam-shaping means, a polarizer, allowing, during the operation of the apparatus, to transmit the collimated beam from one of said beam-shaping means to cause the total internal reflection of the collimated beam from the other of said beam-shaping means and to obtain a resulting beam on whose axis said focusing means are mounted, downstream of said polarizer. In said focusing zone there is placed at least partly reflecting means. The values of the optical lengths L are selected within the range L−ΔL÷L+ΔL, where ΔL is deviation of said optical lengths L; and the combination of deviations ΔL of the optical lengths and deviations δλ of the wavelengths, for at, least one pair of laser diodes located symmetrically about the adder's optical axis, satisfies the coherence condition, i.e. ΔL≦πλ²/8δλ, whereas for the remaining laser diodes, the deviation ΔL of the optical lengths is taken so as not to exceed 10% of said optical lengths L.

The above embodiment of the light-emitting adder, is distinguished from the preceding ones by the use of a polarizer for its designated purpose. However, this becomes only possible due to the following essential features of the system: suitable choice of laser diodes; their provision in each of the planes and appropriate relative positioning of these planes: proper design of the beam shaping means enabling to obtain substantially equal optical lengths L, taking into account the deviations ΔL and δλ satisfying the coherence condition; producing two well-packed substantially coherent integrated light beams in the beam-shaping means provided with beam-transporting means as well as due to the provision of at least party reflecting means positioned within the focusing zone.

It is preferred that said beam-transporting means be designed with a degree of overlapping ranging from 10% to 40%, thereby increasing the brightness and the power output density.

Furthermore beam-transporting means are provided on the trajectory of each light beam, thus leading, once again, to increased brightness and power output density due to the possibility of the self-adjustment of the adder, as well as to an increase in the input coefficient and to the simplification of the beam positioning operation and of the manufacturing process.

With the adopted degree of overlapping in the beam-transporting means equal to 10-40%, the beams leaving the sources overlap to a large extent within the acceptance angle downstream of the focusing means and overlap fully in proximity of the focusing zone. The focusing zone is wholly illuminated by each beam of the source, thereby allowing to obtain a substantially uniform illumination of this zone and of the at least partly reflecting means that may be placed therein in certain embodiments of the invention.

In addition, it is preferred that the beam-transporting means may be made with a predetermined variation of the degree of overlapping, at least in the plane perpendicular to the long dimension of the light-emitting stripes and in at least one direction, and that said beam-transporting means be formed with a predetermined variation of the refractive index. As a result, it becomes possible to reduce the energy loss along the optical path and when illuminating the target area and/or said at least partly reflecting means, as well as to simplify the beam positioning operation.

Besides, the provision of said beam-transporting means allows to render less stringent the requirements placed upon the adjustment of individual emitters, thus simplifying the manufacturing process. The resulting adder assumes a compact appearance with reduced overall dimensions while improving at the same time its principal characteristics, such as the brightness and the power output density.

As has been said before, the number of light sources is given by the formula (11): n=A sin φa/(B sin φb). However, in practice the range between 0.5 n and 1.5 n is considered an acceptable range, and the actual number of sources, herein indicated by N, is preferably taken as an integer within said acceptable range of variations, and more specifically, as the integer closest to the number yielded by the said equation (11).

In such a system, energy losses are lowered along the optical path and when illuminating the target area and/or said at least partly reflecting means, the number of sources used is also reduced.

Preferably, the light sources are arranged in such a manner that the centers of their emitting stripes are located in the plane perpendicular to the long or short dimension of said stripes. In addition, the target area may be placed within the focusing zone. When at least partly reflecting means are used in the target area, the planes of said target area and said reflecting means are made coincident with one another, thus simplifying the manufacturing process and making easier the implementation of the light-emitting adder.

Preferably, the laser diodes are made with wavelengths λ, and optical lengths L such that for any pair of laser diodes located symmetrically about the optical axis of the adder, the combination of deviations ΔL of the optical lengths and deviations δλ of the wavelengths satisfies the coherence condition, i.e. ΔL≦πλ²/8δλ. The above condition allows, when combined with the provision of at least partly reflecting means, the proposed design of the beam-shaping means producing a well-packed light beam and the adopted arrangement of the laser diodes, to obtain an integrated, substantially coherent light beam leaving said beam-shaping means and to achieve the influence of the symmetric laser diodes on one another, as well as on the self-adjustment of the adder taken as a whole, thereby increasing the brightness, the power output density and the concentration of the beam energy in the center of the focusing zone.

Preferably, at least one of the laser diodes—the one that has been called hereinbefore the pilot source—is made with the lowest divergence half-angles (φa, φb and spectral half-width. Said laser diode is positioned on the optical axis of the adder, while other diodes are arranged symmetrically with respect to said axis. Such a solution makes it possible not only to enhance the brightness and the power output; density and to ensure the self-adjustment of the adder, but also to simplify the manufacturing process.

Within the framework of the solutions under consideration, said laser diode having the lowest divergence half-angles φa, φb and spectral half-width is advantageously of single-mode type, thus leading, owing to the possibility of self-adjustment of the adder, to an increase in the brightness and the power output density.

It is expedient to made the laser diodes with at least two values of wavelengths. In such a system an embodiment is possible where at least one beam-shaping means are associated with an odd number, three at least, of laser diodes, the diodes with identical wavelengths being positioned symmetrically relative to the adder's optical axis.

In carrying out the invention, it is possible to use laser diode sources operating at different wavelengths in order to obtain a resultant beam which would contain different wavelengths without any loss of the achieved brightness, thereby enhancing the efficiency of the adder when working at different wavelengths while maintaining at the same time its compactness and light weight. Such high brightness emitters producing substantially coherent or fully coherent light beams at different wavelengths concentrated along a same optical axis may be applied to TV appliances, diagnostic systems etc.

In a preferred aspect., the invention comprises a light unifier, having two groups of light sources which emit parallel light beams of a rectangular cross-section, and a target area onto which the light energy is focused, which two groups of light sources are symmetrical with respect to an axial plane. Each of said groups is provided with beam-shaping means, which comprises transverse collimators, beam deflectors and means for juxtaposing the deflected beams to form a partial unified beam. The transverse collimators, the juxtaposing means, the beam deflectors and the two partial unified beams are symmetrical with respect to the axial plane. The partial unified beams become juxtaposed to form a unified beam. The light unifier further comprises a longitudinal collimator for longitudinally collimating the unified beam and means for focusing the unified beam onto the target area.

In an embodiment of said aspect of the invention, the light unifier produces two partial unified beams that are not juxtaposed, but leave a gap between them which is equal or almost equal to the transverse side of the deflected beams. The light unifier further comprises an additional light source and an additional transverse collimator having their axes on the axial plane of the unifier and producing an axial beam parallel to the deflected beams and inserted in said gap between the partial unified beams. The unified beam is formed by the juxtaposition of said partial unified beams and said axial beam.

The invention therefore further comprises a method for forming a unified light beam from a plurality of individual, emitted beams, preferably laser beams, said individual beams having a rectangular cross-section in any plane perpendicular to the direction of propagation, which cross-section has a long (longitudinal) side and a short (transverse) side, and wherein the divergence in the transverse direction is higher than the divergence in the longitudinal direction, which method comprises:

a) collimating the beams in the transverse direction at a point at which the sum of the short sides of the beams is closer to and preferably slightly larger than their long sides,

b) thereafter, deviating them in such a way as to juxtapose them to form a unified beam,

c) thereafter, when the unified beam has assumed a square cross-section, collimating the same in the longitudinal direction, and

d) finally, focusing the unified, square beam onto the target area to attribute to it the desired final cross-section.

It should be stressed that the collimations need not be total, but may leave a certain degree of divergence, and skilled persons will know how to carry out the invention taking said residual degree of divergence into account. This should be understood as implied whenever collimation is mentioned.

### BRIEF DESCRIPTION OF THE DRAWINGS

In the drawings:

FIGS. 1A and 113 are a schematic representation of a light emitting adder according to an embodiment of the invention, FIG. 1A being a lateral view and FIG. 113 a plan view;

FIG. 2 is a schematic plan view of another embodiment, more fully illustrated in FIG. 7, wherein the target represented by an optical fiber;

FIG. 3 is a schematic plan view of a further embodiment, comprising a polarizer;

FIG. 4 is a schematic plan view of a light unifier according to another embodiment of the invention;

FIGS. 5a, 5b, 5C and 5d are schematic cross-sections of the beams shown in FIG. 4, taken on the planes indicated in FIG. 4 as I-1, 11-11, III-111 and IV-IV respectively; and

FIG. 6 is a schematic cross-section illustrating a modification of the invention;

FIG. 7 is a schematic plan view of alight unifier according to another embodiment of the invention; and

FIG. 8 is a schematic plan view of a light more schematically illustrated in FIG. 2.

### DETAILED DESCRIPTION OF PREFERRED EMBODIMENTS

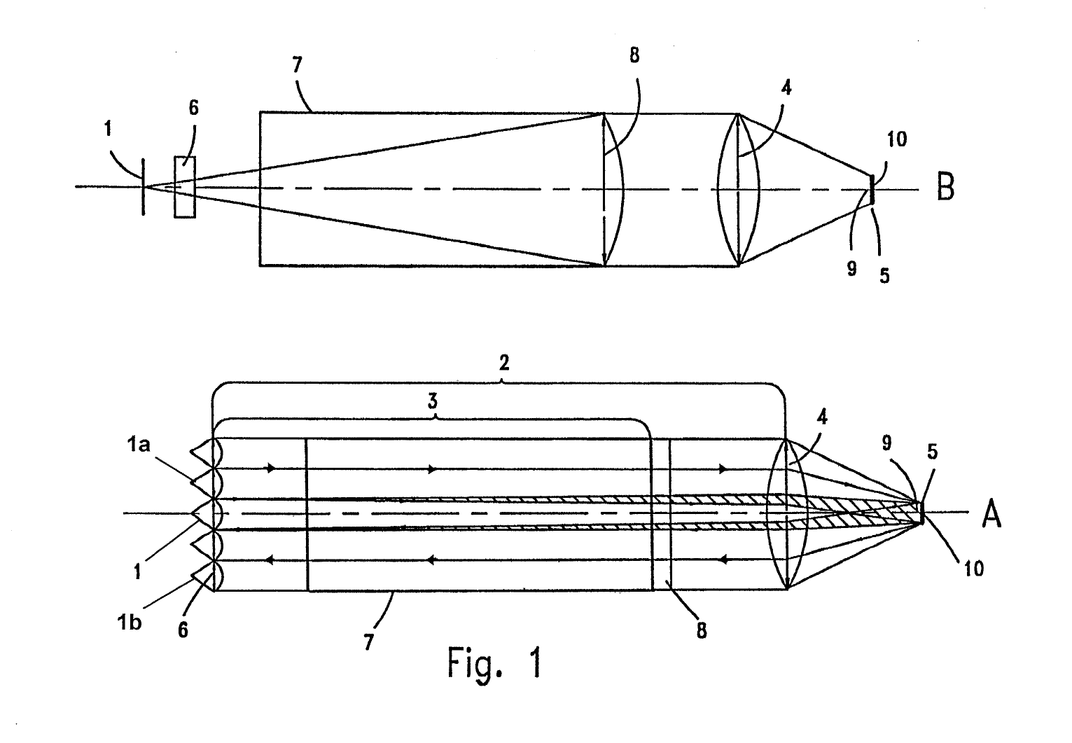

Referring now to FIG. 1, the proposed light-emitting adder (briefly called hereinafter “adder”) according to a first embodiment comprises light sources 1 (briefly called hereinafter “sources”), imaging means 2 composed of shaping means 3 and focusing means 4, and a focusing zone 5. The direction of the long dimension of the emitted light stripes is considered to be parallel to the x-axis and the direction of the short dimension is considered to be parallel to the y-axis. It is assumed that the sizes of the long side “a” and the short side “b” of the emitted stripe are identical for all the sources 1. All the light sources are located in a same plane, which is perpendicular to the long or short dimension of the stripes and extends preferably through the center thereof. The shaping means 3 comprise means 6 for collimating along the y-axis , beam-transporting means 7 and means 8 for collimating along the x-axis. The focusing zone 5 accommodates at least partly reflecting means 9 and, in the example illustrated, a target area 10. The collimating means 6 are placed immediately after the light sources 1. The light sources 1 are spaced apart from the focusing zone 5 at substantially equal distances corresponding to the optical lengths L. The optical lengths L are selected, for each source, such that they differ from one another by not more than a value ΔL amounting to 2-8%, but not more than 10%, of the optical lengths L. The target area 10 may be positioned either within the focusing zone 5 or farther on the optical axis. In both cases (in the latter case, provided the use of suitable optics), the target area 10 will be completely occupied by all the beams issuing from the sources 1.

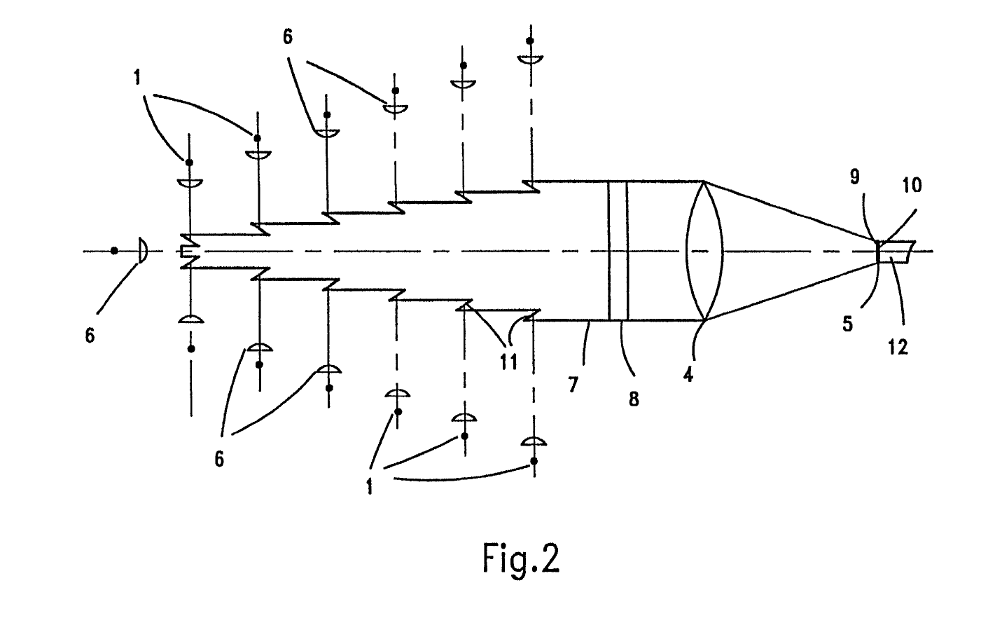

In accordance with the second embodiment (FIG. 2), the claimed light-emitting adder is designed as follows. Used as light sources are laser diodes 1 arranged in a same plane which is perpendicular to the long or short dimension of the emitted light stripes and extends preferably through the center thereof. In this particular case, there are 13 laser diodes 1. The light-emitting elements of the laser diodes I are fabricated from a heterojunction structure GaAs-lnGaAs having lasing wavelength λ=670±2 nm with a spread between different diodes lying within the limits ±3 nm. In the cross-section perpendicular to the optical axis of each diode 1, the size of the emitted light stripe is of (100×1) μm². The long side of the stripes is considered to be parallel to the x-axis and the short side to the y-axis. They are located in the plane y-z, which extends through the centers of the respective stripes. The laser 1 located on the optical axis of the adder is the pilot source. In this particular example, the combination of the deviations ΔL of the optical lengths and the deviations δλ of the wavelengths, for one pair of laser diodes 1, namely for the second pair after the pilot source. located symmetrically about the adder's optical axis, satisfies the coherence condition, i.e. ΔL≦πλ²/8δλ. As to other diodes, their optical lengths L are characterized by a spread of 4±1% of the corresponding optical length L.

As stated above, imaging means 2 (see FIG. 1B) are composed of shaping means 3 and focusing means 4. Shaping means 3 include, as viewed from the laser diodes 1, a system of cylindrical lenses 6 ensuring the collimation along the y-axis, which are positioned on each optical axis of the laser diodes I and having focal lengths of 0.26±0.02 cm, beam-transporting means 7 provided with input folding prisms 11 made of glass, and a cylindrical lens 8 collimating the beam along the x-axis with a focal length of 4.6±0.2 cm. Then follow the focusing means formed by a focusing lens 4 having identical (±1 μm) focal lengths along the x-axis and y-axis equal to 2.5±0.03 cm. Mounted farther on the optical axis is an optical fiber 12 whose end is positioned within the focusing zone 5 and covered with a partly reflecting coating 9 having a reflection factor P in the order of 7±0.5%.

In operation, the supply of the working current to the laser diodes 1 gives rise to the emission of a coherent light with a predetermined wavelength, or wavelengths, and a corresponding spectral half-width. Passing along the optical paths from the sources 1 to the focusing zone 5, the light produced by each of the sources 1 reaches the target area 10 placed within said zone 5. In this travel, a part of the light is reflected from the above-mentioned at least partly reflecting means 9, made in the form of the coating 9 covering the target area 10, and then comes back to the imaging means 2 following, however, another optical path, all as indicated in FIG. 1. In said figure the solid line shows the light leaving the source 1a, which is second as viewed from above in the figure, then reflected from the at least partly reflecting means 9 and finally coming back to the source 1b which is second as viewed from below in the figure. The broken line designates the path of the light emitted by the central source 1 and the hatched regions illustrate examples of beams overlapping.

In the beam-transporting means 7, there is operated a partial mixing of beams (by a value of about 25±5%). The light collimated in two mutually perpendicular planes reaches the focusing means formed by the focusing lens 4 having identical (±1 μm), focal lengths along the x-axis and y-axis equal to 2.5±0.03 cm. After having passed through said focusing lens 4, the beams will be substantially fully mixed within the acceptance angle of the target area 10 both along the x-axis and the y-axis, thus entirely illuminating, with each original part of the light, the total target area 10. i.e. a square spot of 40×40 μm², the divergence in mutually perpendicular directions being equal to 14±0.2 mrad. Said target area 10 is constituted by the end of the optical fiber 12 having a diameter of 50 μm with a numerical aperture NA of the receiving fiber equal to 0.21±0.01. The at least partly reflecting means 9 are made in the form of a coating deposited on the end of said optical fiber 12.

Each laser diode has a power output P₁ averaging in the order of 250±0.10 mW. We achieved a resulting power output Pₒᵤₜ amounting to 1.5 W over an area of 40×40 μm². So, it is evident that using few light sources, a considerably greater power output density and a higher brightness are achieved.

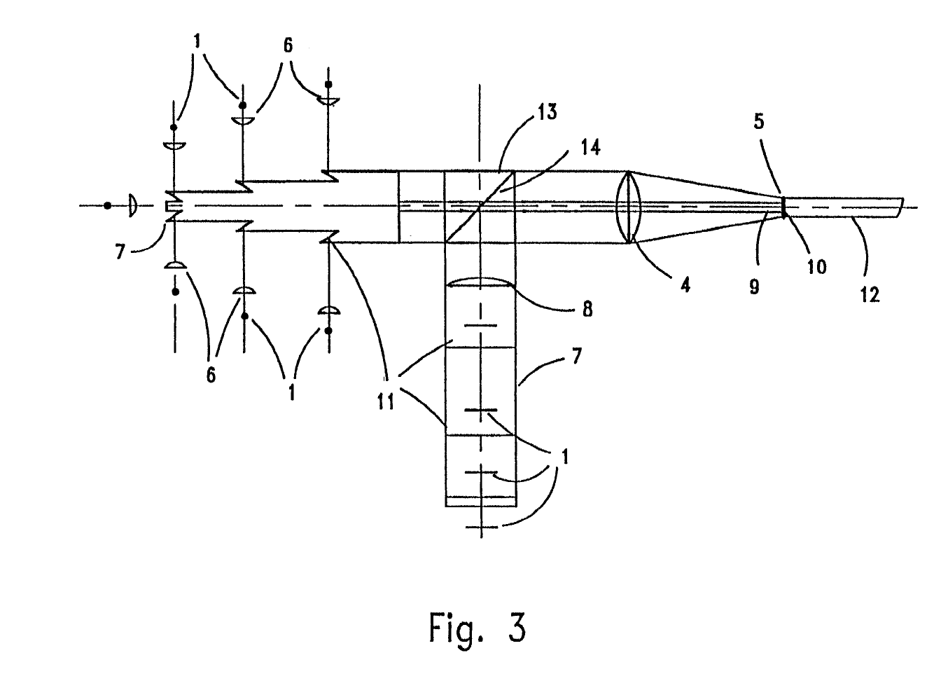

In accordance with the embodiment illustrated in FIG. 3, the claimed light-emitting adder is composed of two systems of laser diodes 1 performing the function of light sources and two shaping means associated with each of said systems of laser diodes 1. The laser diodes 1 are located in two mutually perpendicular planes, each of which is perpendicular to the long or short dimension of the respective emitted light stripes and extends preferably through their center. Each shaping means is composed of a plurality of means 6 for collimating in the direction parallel to the short dimension (the y-dimension) of the light stripes. Each shaping means further comprise at east one beam-transporting means 7 capable, on at least a part of its extent, of partly overlapping the beams, followed by means 8 for collimating in the direction parallel to the long dimension (the x-dimension) of the stripe. The respective optical axes of the shaping means of both laser system, which constitute those of the beam-transporting means 7 and of the means 8 collimating in the direction parallel to the long dimension of the stripe, are mutually perpendicular and intersect with one another downstream of the shaping means 3 and upstream of the focusing means 4 and are positioned in the planes corresponding to the location of the laser diodes 1. The planes of location of the laser diodes 1 intersect downstream of the shaping means 3. The intersection point of optical axes of the shaping means of the two laser systems is on the line of crossing of said planes of location of the laser diodes 1. The additional polarizer 13 is placed with its plane of polarization 14 at the intersection of said optical axes of the shaping means. Mounted downstream of the polarizer 13 are focusing means 4, while the focusing zone 5 incorporates the at least partly reflecting means 9. The output end of each laser diode 1 is spaced apart from the focusing zone 5 at substantially equal distance corresponding to the optical lengths L. In this system, the combination of deviations ΔL of the optical lengths and deviations δλ of the wavelengths is taken, for at, least one pair of laser diodes 1 located symmetrically with respect to the adder's optical axis, so that it satisfies the coherence condition, i.e. ΔL≦πλ²/8δλ, whereas for the remaining laser diodes the deviation ΔL of the optical lengths is taken so as not to exceed 10% of said optical lengths L.

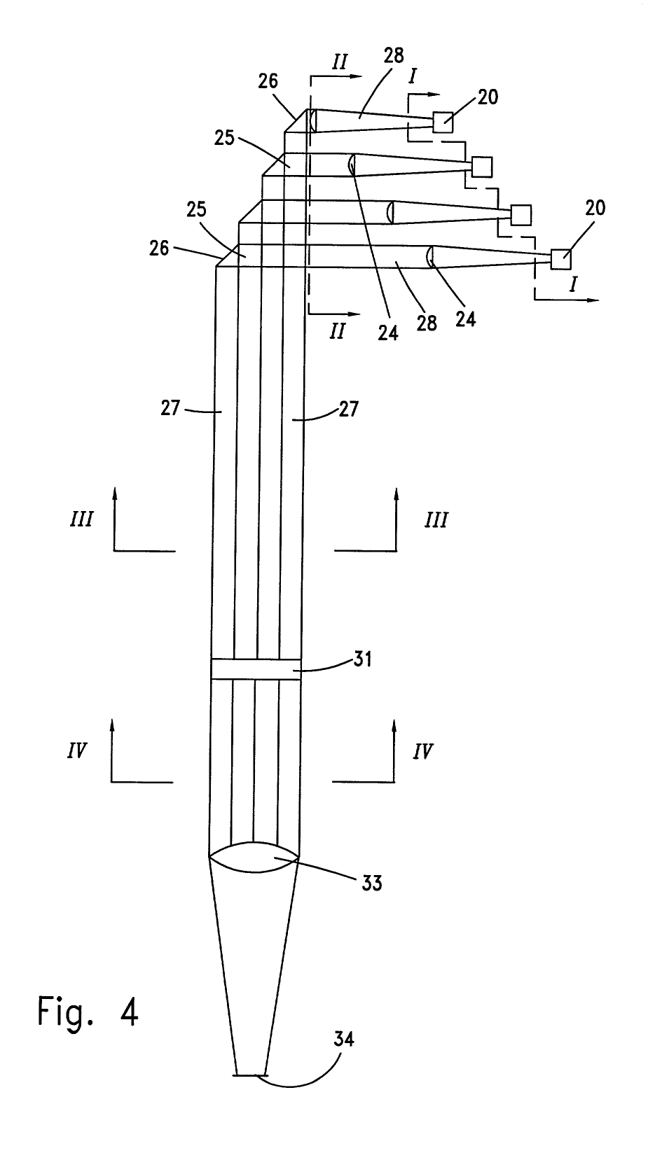

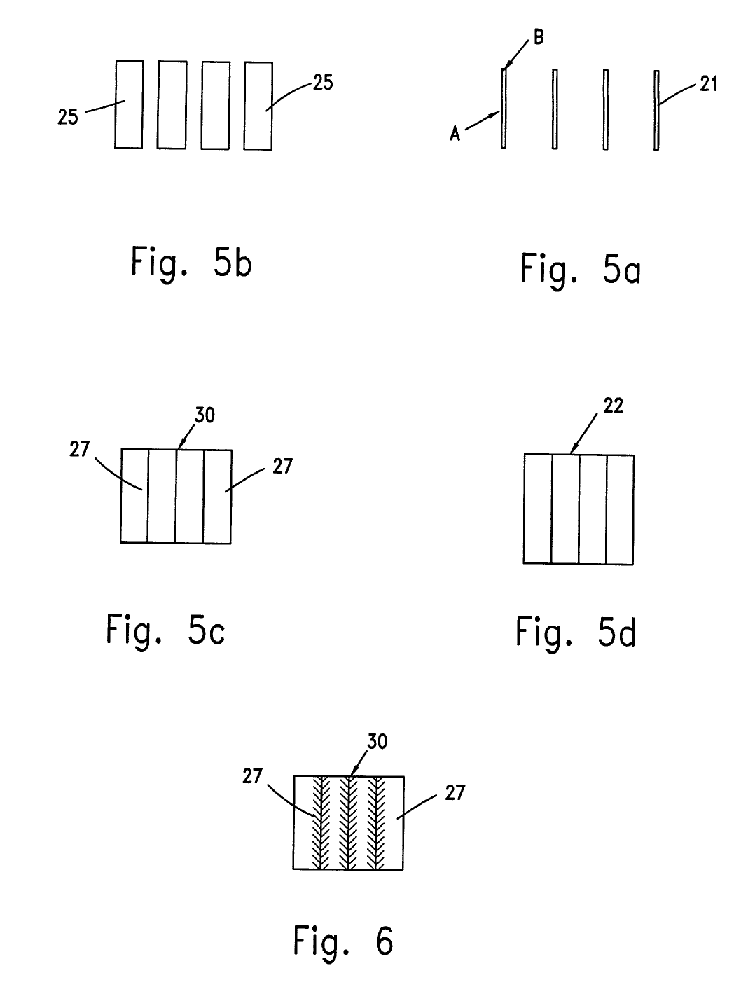

FIG. 4 illustrates still another embodiment of the invention. In FIG. 4 only four lasers are shown, but this is merely for the purpose of illustration, and in general the number of lasers will be higher, as desired in each case. The lasers, schematically indicated at 20, emit beams through rectangular openings 21 (see FIG. 5a), which have a long, longitudinal side of length A and a short, transverse side of length B. FIG. 5a, which is a staggered cross-section of the laser beams close to their emission (as indicated in said figure by the staggered trace I-I), can be interpreted as approximately illustrating the openings 21. In actual apparatus, as has been said, the length A of the longitudinal side is much higher than the length B of the transverse side, their ratio being, e.g., 100. Thus, A may be equal to 100 microns, while B may be equal to 1 micron. In the drawings, for purposes of illustration, the lengths of the sides is shown as quite different from what they would be in actual devices and their ratio is much lower than it would be.

The cross-section of each beam, at is emission, is equal to the openings 21. As the beams travel away from the sources, they diverge, viz. spread out, in segments 28, as shown in FIG. 4, until they impinge each on a transverse collimator 24, at which point they have larger transverse dimensions due to divergence, which they keep after the transverse collimation (assumed to be complete) as shown in FIG. 5b, a cross-section taken on plane II-II of FIG. 4. The transverse collimators are preferably cylindrical lenses, as schematically shown in the drawing, but may be different optical elements. They reduce the transverse divergence ideally to 0, as shown in FIG. 4, although in practice some transverse divergence may remain. Transversely collimated beams 25 impinge on deflectors 26, which are schematically indicated as prisms, but may be any other suitable reflecting device, which deflect the beams by 90° to produce deflected beams 27. The position of the deflectors 26 is such that the deflected beams 17 are juxtaposed, as seen in FIG. 4, but preferably slightly overlapped, e.g. from 10% to 40%. This means that in principle the deflectors are successively displaced parallel to the path of the collimated beams—each reflector with respect to the preceding one—by a distance equal to a short side of the beams, as clearly seen in FIG. 4. However, their displacement could be slightly shorter than said short side, whereby to cause adjacent beams to overlap by an amount not greater than 40%, or could be slightly longer, if the beams still retain some lateral divergence and therefore will spread out sufficiently to become juxtaposed. The short sides of the beams are such as to produce a unified beam 30 that will be square when it reaches longitudinal collimator 31, as will be explained hereinafter. The configuration of the unified beam when it is generated is shown in FIG. 5c, which shows a cross-section thereof taken on plane III-III of FIG. 4.

The cross-section of the unified beam, as in FIG. 5c, is still not exactly square, because its transverse side is slightly larger than its longitudinal side. It should be understood that the words “transverse” and “longitudinal”, when referred to the unified beam have the same meaning as when they referred to the originally emitted beams, in spite of their deflection, viz. indicate directions respectively parallel to the short and to the long side of the individual beams.

As the unified beam 30 proceeds from it formation and from plane III-III, its long side will continue to diverge and expand, according to the divergence half-angle (pa, until it reaches longitudinal collimator 31, at which point its long side will have expanded to become equal to its short side, to produce a square cross-section 32, as illustrated in FIG. 5d, which is a cross-section taken on plane IV-IV of FIG. 4.

It will be noted, and is clearly seen in FIG. 5, that the paths traveled by the individual beams from the deflectors 36 to the longitudinal collimator 31 are different. In order to render the primary optical paths of the different beams equal, this difference must be compensated by an equal, but opposite, difference in the distances of the sources and of the transverse collimators 34 from the deflectors 36.

Longitudinal collimator 31 annuls the longitudinal divergence of the square, unified beam 32. The square, unified beam 32 now impinges on a focusing device 33, which is indicated in the drawings as a spherical lens, but may be any other suitable, and particularly more complex, optical device, which focuses beam 32 on the target area 34 and concentrates it to such a size as may be convenient for introducing it into any small optical receiver or transmitter, such as an optical fiber. The concentrated unified beam will therefore have a side which is close to a corresponding dimension of the optical receiver, in the case of an optical fiber close to its diameter.

As has been said hereinbefore, if the actual physical target, e.g. an optical fiber, is not located in a target area, the unified beam will be transmitted by any suitable optical device, which may be called “a forwarding device”, from the target area to the target.

Desirably, the laser sources and the transverse collimators will be so positioned that the differences in the distances that the beams travel from the source to the respective deflector compensate the differences in the distances traveled by the deflected beams, so that the optical paths of all the beams, viz. the distances between their sources and the target area, are ideally equal or differ from one another by small amounts.

As a purely illustrating numerical example, and assuming that both collimators annul the respective divergence, it will be assumed that the parameters defined hereinbefore have the following values:

n=10

A=100 μm

B=1.3 μm

A+2(d+D)tan gφa=B+2d tan gφb

tan gφa=0.1

tan gφb=0.67

D+d=54.22 mm.

Then, the condition A+2(d+D)tan gφa=n(B+2d tan gφb) gives:

100 μm+2(55 mm)0.1=10(1.3 μm+2d 0.67) or 13.4. d=11 mm+87=11.987 mm;

d=0.83 mm; and this is the distance at which the transverse collimators should be placed from the sources.

Since the individual beams, in this example, will have a transverse width of 1.3 μm=2 D 0.67=1.12 mm, the prisms, if prisms are used to deflect the beams, should have a slanted size of about 1.5 mm.

While the deflected beams 27 are shown in FIG. 4 to be exactly parallel and juxtaposed, the desired rectangular cross-section of the combined beam can be achieved by directing various beams, that are not exactly parallel and juxtaposed, by means of the deflectors 26 in such a way that they will become adjacent or partially overlapping when they impinge on the longitudinal collimator 21. FIG. 6 schematically-illustrates a variation of FIG. 5d in which a unified beam 30 comprises in which the partly overlapping individual beams 27, the overlapping areas being indicated by cross-hatching.

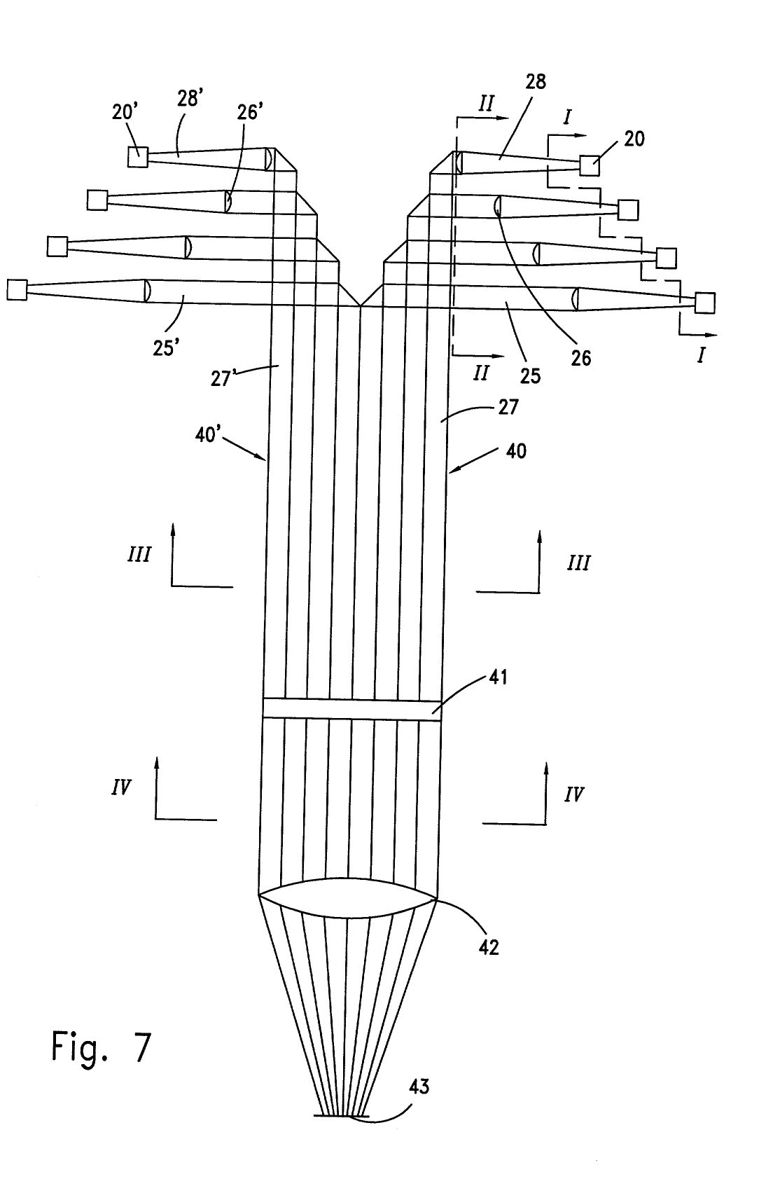

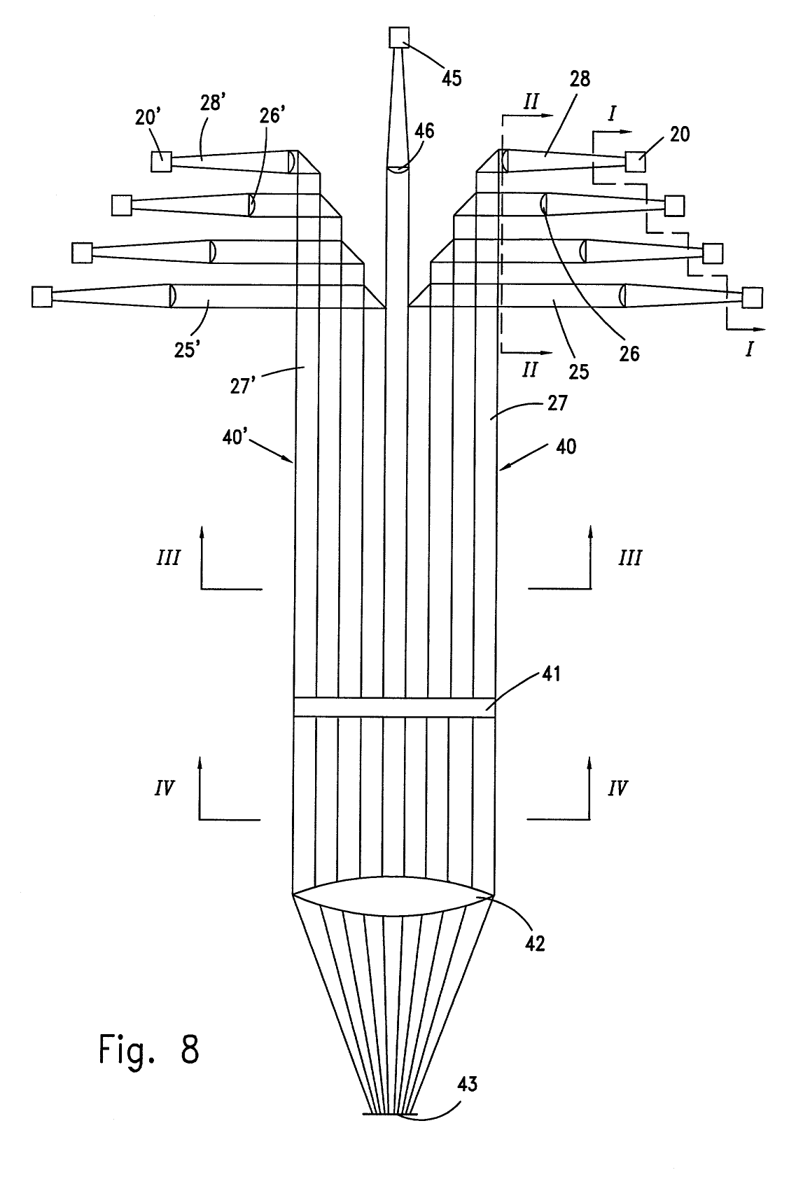

The combination of light sources, transverse collimators and beam juxtaposing means—which may be called, for brevity's sake, “unified-beam former”—may be effected more than once in a light unifier according to the invention, to produce a more powerful unified beam. An example is illustrated in FIG. 7, wherein longitudinal collimator 41, focusing means 42 and target area 43 are common to two unified-beam formers, which are generally indicated at 40 and 40′ and are symmetrical with respect to an axial plane of the light unifier. Each of the two symmetrical unified-beam formers comprises transverse collimators and beam deflectors, symmetrical with respect to said axial plane, and having the same features that have been described with respect to the collimators and deflectors of FIG. 4. It may be said that such a light unifier is constituted by two light unifiers as described with reference to FIG. 4, disposed symmetrically with respect to an axial plane. In FIG. 8, the elements corresponding to those of FIG. 4 are indicated by the same numerals for beam former 40 and by corresponding accented numerals for former 40′.

FIG. 8 illustrates such an apparatus, which however is further improved by providing a central laser source 45 with its transverse collimator 46, all coaxial to the axial plane of the apparatus, viz. the plane of symmetry of the two unified-beam formers 40-40′. The beam of source 45 can propagate directly to collimator 41 without undergoing deflection. The only condition is that the central source be so placed as to have the same or nearly the same optical length as the other sources, the beams of which have been deflected. Preferably, the difference in optical length ΔL between laser diodes of a pair placed symmetrically with respect to the adder optical axis should meet the coherence requirement ΔL≦πλ²/8δλ, wherein λ is the wavelength of a laser diode and δλ is the deviation of the wavelength.

In the combination of two unified-beam formers illustrated in FIG. 8, all the laser sources are located on the same plane. It will be appreciated that small deviations from said plane are permissible and can be compensated by suitably slanting the reflecting beams.

However, it is possible to combine two unified-beam formers (indicated hereinafter as “BFs”) which are not coplanar, viz. wherein the laser sources of one such former are located in a different planes from those of the other such former, the two planes making an angle preferably of 90°. Even in this case, the longitudinal collimator, the focusing means, and the target area are common.

The radiation of a laser diode is known to be strongly polarized. The polarization plane of the unified beam of the left BF should be perpendicular to that of the bottom BF. A polarizer 13 used in our scheme transmits the unified beam of the left BF and completely reflects the unified beam of the bottom BF.

Thus, one creates a total beam after polarizer 43 that has two perpendicular polarization planes and is made up of the two unified perpendicular beams of two SFs.

Preferred kinds and sizes of the unifier components are as follows:

Laser sources: 6.5×8 mm C-mount package.

Emitting body: A=100 μm, B=1.3 μm, NA//diode=0.1, NA⊥diode=0.55, φa=6°, and φb≅34°.

Transverse collimators: focal distance F=1.28 mm, Ø=8 mm, h=8 mm.

Reflecting means: 55×27×22 mm, facet=1.5 mm.

Longitudinal collimators: 14×14 mm, F=55.5 mm.

Focusing means: Ø=13 mm, 1=20 mm, F=25 mm.

Cross-section of the focused, unified beam: 12×13.3-mm collimated beam and 40×42 μm focused beam at the target area.

Therefore, the inventors achieved a considerably higher power output density and an increased brightness of the integrated, well-packed and substantially coherent narrow light beam generated by few light sources which may operate at different, wavelengths. Furthermore, the beam positioning in such sources, as well as the process of manufacture of the entire system, including its component parts, are made easier.

Light-emitting adders are widely usable in pumping solid-state lasers. in producing laser-based industrial equipment, measuring appliances, medical instrumentation, marking devices, communication facilities, as well as systems for long-distance power and data transmission.

While embodiments of the invention have been described by way of illustration, it will be apparent that the invention may be carried out with many modifications, variations and adaptations, without departing from its spirit or exceeding the scope of the claims.

We claim:

1. Light unifier, having a plurality of light sources which emit parallel light beams of a rectangular cross-section, and a target area onto which the light energy is focused, characterized in that it further comprises beam-shaping means, which comprises transverse collimators, means for juxtaposing the emitted beams to form a unified beam, a longitudinal collimator for longitudinally collimating said unified beam, and means for focusing said unified beam onto said target area.

2. Light unifier according to claim 1, wherein the light sources are laser sources.

3. Light adder according to claim 1, wherein the light beams cross-section has a long, longitudinal side and a short, transverse side, and the ratio of the longitudinal side to the transverse side is from 20 to 120.

4. Light unifier according to claim 2, wherein the laser sources are chosen from among SDL-6370-A, SDL-6380-A, SDL-6380-L-2, S-915-500C-50-x, S-915-1000C-100-x and S-915-1500C-150-x.

5. Light unifier according to claim 1, wherein the light beams have a transverse and a longitudinal divergence and the ratio of the transverse divergence to the longitudinal divergence is higher than 1.

6. Light unifier according to claim 1, wherein the beam-shaping means comprise:
A—transverse collimators;
B—a beam adder for juxtaposing the beams to form a unified beam;
C—means for imparting to the unified beam a square cross-section;
D—a longitudinal collimator, located at a point at which the unified beam has been imparted a square cross-section; and
E—means for focusing the collimated, unified beam onto the target area.

7. Light unifier according to claim 6, wherein the transverse collimators are placed at such a distance from the sources that the sum of the short sides of the beams at the point at which at which the beams reach the respective transverse collimators is equal to the long side of each of them at the point at which the beams reach the longitudinal collimator.

8. Light unifier according to claim 6, wherein the beam adder comprises means for deflecting the beams.

9. Light unifier according to claim 8, wherein the means for deflecting the beams are reflective mean.

10. Light unifier according to claim 8, wherein the means for deflecting the beams are as to produce a deflection by an angle of 90° and to leave the beams parallel to one another.

11. Light unifier according to claim 6, wherein the beam adders are so located as to make the optical paths of the several beams as close to one another as possible.

12. Light unifier according to claim 6, further comprising means for transferring the focused, unified beam from the target area to a target spaced therefrom.

13. Light unifier according to claim 1, wherein the beam-shaping means are such as to bring the individual, emitted beams to juxtaposition or partial overlap, to form a square unified beam, before they are collimated in the longitudinal direction, and as to bring the individual, emitted beams to juxtaposition or partial overlap, to form the unified beam, by deflecting them.

14. Light unifier according to claim 9, wherein the reflecting means are chosen from among prisms and mirrors.

15. Light unifier according to claim 6, wherein the deflecting means are such and so positioned as to cause the deflected beams to overlap to an extent from 10 to 40% of the cross-sectional area of any one of the overlapping beams.

16. Light unifier according to any one of claims from 1 to 15, wherein the components are chosen as follows:
Laser sources: 6.5×8 mm C-mount package.
Emitting body: A=100 μm, B=1.3 μm, NA//diode=0.1, NA⊥diode=0.55, φa=6°, and φb≅34°.
Transverse collimators: focal distance F=1.28 mm, Ø=8 mm, h=8 mm.
Reflecting means: 55×27×22 mm, facet=1.5 mm.
Longitudinal collimators: 14×14 mm, F=55.5 mm.
Focusing means: Ø=13 mm, 1=20 mm, F=25 mm.

17. Light unifier, having two groups of light sources which emit parallel light beams of a rectangular cross-section, and a target area onto which the light energy is focused, characterized in that said two groups of light sources are symmetrical with respect to an axial plane, and each is provided with beam-shaping means, which comprises transverse collimators, beam deflectors and means for juxtaposing the deflected beams to form a partial unified beam, said transverse collimators, said juxtaposing mean, said beam deflectors and said two partial unified beams being symmetrical with respect to said axial plane and said partial unified beams being juxtaposed to form a unified beam, said light unifier further comprising a longitudinal collimator for longitudinally collimating said unified beam and means for focusing said unified beam onto said target area.

18. Light unifier according to claim 17, wherein the two partial unified beams are not juxtaposed and which further comprises an additional light source and an additional transverse collimator having their axes on the axial plane of the unifier and producing an axial beam parallel to the deflected beams and inserted between the partial unified beams, a unified beam being formed by the juxtaposition of said partial unified beams and said axial beam.

19. Light unifier according to claim 1, having a number of light sources such as to permit to obtain a unified beam that has a square cross-section and the same divergence on all its sides.

20. Light unifier according to claim 1, having a number of light sources comprised in the range 0.5 n to 1.5 n, wherein n=A sin φa/B sin φb, A and B are the long and short side, respectively, and φa and φb are the longitudinal and transverse divergence half-angles, respectively, as defined herein, of the emitted beams.

21. Light unifier according to claim 20 having a number of light sources N that is the closest integer to the value n=A sin φa/B sin φb, wherein A and b are the long and short side, respectively, and φa and φb are the longitudinal and transverse divergence half-angles, respectively, as defined herein, of the emitted beams.

22. Light unifier according to claim 1, further comprising reflecting means for reflecting the light beam emitted by a source back to another source.

23. Light unifier comprising a plurality of laser diodes arranged so as to have at least two sources in each of two mutually perpendicular planes, each of these planes being perpendicular to the long dimension of the respective light-emitting stripes, further comprising: a) a first and a second beam-shaping means, said beam-shaping means being as defined in claim 1, the optical axes of said beam-shaping means being mutually perpendicular, and b) at the intersection of said beam shaping means, a polarizer.

24. Method for forming a unified light beam from a plurality of individual, emitted beams, preferably laser beams, said individual beams having a rectangular cross-section in any plane perpendicular to the direction of propagation, which cross-section has a long (longitudinal) side and a short (transverse) side, and wherein the divergence in the transverse direction is higher than the divergence in the longitudinal direction, which method comprises:
a) collimating the beams in the transverse direction at a point at which the sum of the short sides of the beams is closer to and preferably slightly larger than their long sides,
b) thereafter, deflecting them in such a way as to juxtapose them to form a unified beam;
c) thereafter, when the unified beam has assumed a square cross-section, collimating the same in the longitudinal direction, and
d) finally, focusing the unified, square beam onto the target area to attribute to it the desired final cross-section.

25. Method according to claim 24, further comprising causing the unified beam to have the same divergence on all its sides.
